(19) United States
(12) Patent Application Publication
(10) Pub. No.: US 2025/0266814 A1
(43) Pub. Date: Aug. 21, 2025

(54) ELECTRONIC PULSE GENERATORS AND METHODS THEREOF

(71) Applicant: Huawei Technologies Canada Co., Ltd., Kanata (CA)

(72) Inventors: Ke Wu, Saint-Laurent (CA); MuhibUr Rahman, Ottawa (CA)

(21) Appl. No.: 19/195,232

(22) Filed: Apr. 30, 2025

Related U.S. Application Data
(63) Continuation of application No. PCT/CA2022/051887, filed on Dec. 22, 2022.

(51) Int. Cl. H03K 5/01; H03K 5/00

(52) U.S. Cl. CPC H03K 5/01; H03K 2005/00019

(57) ABSTRACT

A module has an input port, an output port, and a first and a second conductive path arranged in parallel and connecting the input port and the output port, the first path having a first pulse compressor, and the second path having a second pulse compressor and a delay element. The module is suitable for generating a Gaussian doublet pulse, where the first pulse compressor is for providing rise-time compression, the second pulse compressor is for providing fall-time compression, and the delay element is adjustable. The module may further have a pulse-forming network for transforming the Gaussian doublet pulse to a monocycle doublet pulse. Each of the first pulse compressor, the second pulse compressor and the delay network may be non-linear transmission lines.

### CROSS-REFERENCE TO RELATED APPLICATION

The present application is a continuation of Patent Cooperation Treaty Application No. PCT/CA2022/051887, entitled “ELECTRONIC PULSE GENERATORS AND METHODS THEREOF,” filed on Dec. 22, 2022, the entirety of which is incorporated by reference herein.

### TECHNICAL FIELD

The present disclosure relates generally to electronic pulse generators, and in particular, to electronic pulse generators comprising non-linear transmission lines.

### BACKGROUND

A non-linear transmission line (NLTL) is an inductor-capacitor (LC) ladder network that is generally loaded periodically with lumped inductors and reversely biased varactor diodes. NLTLs may also have different configurations comprising other periodically loaded non-linear elements and/or completely distributed non-linear media. NLTLs may exhibit non-linearity due to varactor diodes, as well as dispersion due to structural periodicity. Harmony between dispersion and non-linearity can be made through a voltage traveling pulse called “soliton.” This phenomenon makes NLTLs a suitable candidate for pulse generation and compression in microwave systems and ultra-fast electronics. NLTLs have been used for generating fast electrical transitions, including rising edge compression, falling edge compression, and overall pulse compression. As those skilled in the art understand, pulse compression is a technology of transmitting a long pulse, and processing the received version of the pulse to a narrow pulse for achieving a good range resolution.

### SUMMARY

The present disclosure provides modules and methods for attenuators suitable for applications including modern communications systems that require high non-linearity, low power consumption, and low temperature dependency. Some embodiments of modules and methods disclosed herein provide attenuators that preserve signal integrity while controlling the signal power. Some embodiments of modules and methods disclosed herein have a high dynamic range, low insertion loss, wide attenuation range, and wide frequency bandwidth.

According to one aspect of this disclosure, there is provided a module comprising an input port; an output port; and a first and a second conductive path arranged in parallel and connecting the input port and the output port, the first path comprising a first pulse compressor, and the second path comprising a second pulse compressor and a delay element.

In an embodiment, the first pulse compressor is a first non-linear transmission line (NLTL) comprising one or more step recovery diodes (SRDs).

In an embodiment, the first pulse compressor comprises lumped inductors and reversely biased varactor diodes.

In an embodiment, the first NLTL comprises four sections.

In an embodiment, the first NLTL comprises five or more sections.

In an embodiment, the second pulse compressor is a second NLTL comprising one or more SRDs.

In an embodiment, the second pulse compressor comprises lumped inductors and reversely biased varactor diodes.

In an embodiment, the second NLTL comprises four sections.

In an embodiment, the second NLTL comprises five or more sections.

In an embodiment, the first pulse compressor comprises a first NLTL comprising one or more varactor diodes for rise-time compression, and the second pulse compressor comprises a second NLTL comprising one or more varactor diodes for fall-time compression, the one or more varactor diodes of the second pulse compressor arranged with a polarity opposite a polarity of the one or more varactor diodes of the first pulse compressor.

In an embodiment, the delay element is a variable delay network.

In an embodiment, the delay element is an NLTL.

In an embodiment, the delay element comprises lumped inductors and reversely biased varactor diodes.

In an embodiment, the module is for generation of a Gaussian doublet pulse.

In an embodiment, the module further comprises a pulse-forming network proximate the output port.

In an embodiment, the pulse-forming network is for transforming a Gaussian doublet pulse to a monocycle doublet pulse.

According to one aspect of this disclosure, there is provided a method comprising the steps of receiving an input signal; generating a rise-time component of a pulse; generating a fall-time component of the pulse; and delaying the fall-time component to a delayed fall-time component; combining the rise-time component and the delayed fall-time component to generate an output signal.

In an embodiment, the fall-time component is delayed by an adjustable delay.

In an embodiment, the output signal is a Gaussian doublet pulse.

In an embodiment, the method further comprises transforming the Gaussian doublet pulse to a monocycle doublet pulse.

Corresponding apparatuses and devices comprising means for performing the methods herein are also disclosed. For example, the apparatus comprising means for implementing the methods herein, wherein the apparatus may be a component/module/chipset.

Further, there is provided a non-transitory computer readable medium, wherein the non-transitory computer readable storage medium stores instructions, and when the instructions run on a computer, the computer performs the methods herein.

### BRIEF DESCRIPTION OF THE DRAWINGS

For a more complete understanding of the disclosure, reference is made to the following description and accompanying drawings, in which:

FIG. 1 is schematic diagram of a prior-art pulse generator;

FIG. 2 is a schematic diagram of a prior-art impulse-forming circuit;

FIG. 3 is a schematic diagram of a prior-art waveform generator;

FIG. 4 is a schematic diagram of a prior-art pulse generator;

FIG. 5 is a schematic diagram of an embodiment of a pulse generator module;

FIG. 6 is a schematic diagram of an embodiment of a Gaussian doublet pulse generator module;

FIG. 7 is a schematic diagram of an embodiment of a monocycle doublet pulse generator module;

FIG. 8 is a graph of a response of the Gaussian doublet pulse generator module shown in FIG. 7 with an adjusted delay of 830 picoseconds (ps) between pulses;

FIG. 9 is a graph of a response of the Gaussian doublet pulse generator module shown in FIG. 7 with an adjusted delay of 410 ps between pulses;

FIG. 10 is a graph of a response of the Gaussian doublet pulse generator module shown in FIG. 7 with an adjusted delay of 100 ps between pulses;

FIG. 11 is a graph of a response of an embodiment of a monocycle doublet pulse generator with an adjusted delay between pulses;

FIG. 12 is a graph of a calculated power spectrum of an embodiment of a monocycle doublet pulse generator; and

FIG. 13 is a flowchart illustrating a method for operating a module.

### DETAILED DESCRIPTION

Although embodiments are described herein with reference to the accompanying drawings, those of skill in the art will appreciate that variations and modifications may be made without departing from the scope thereof as defined by the appended claims.

In some embodiments disclosed herein, modules and methods relating to pulse generators comprise one or more pulse compressors, wherein each compressor may comprise one or more non-linear transmission lines (NLTLs). In some embodiments disclosed herein, an NLTL is also used as a variable delay network in a pulse compression system or method for providing an ultrashort Gaussian doublet pulse generator, Gaussian triplet pulse generator, or monocycle doublet pulse generator. Ultrashort pulses have many practical applications such as in ultra-broadband and ultrafast systems, for example, time-domain reflectometry, sampling oscilloscopes, frequency synthesizer, and ultra-wideband (UWB) communication applications. However, many existing, commercially available ultrashort pulse generators are generally not adequate for future radar, terahertz (THz) applications, and high-speed millimeter-wave applications.

Devices suitable for UWB applications may be used for impulse radar developments in medical, industrial, and military fields. In these applications, the generation of clean, ultra-short picosecond (ps) pulses having appropriate pulse compression and a pulse repetition frequency (PRF) is highly desirable. In practice, it is challenging to provide highly efficient short pulses in a module or method having flexible compression capabilities and acceptable ringing behavior.

Impulse radar systems may radiate impulse-like waveforms generally falling into a sub-nanosecond regime having broadband features. Such waveforms of broad bandwidth comprising compressed ps pulses may permit higher resolutions and data rates. Such waveforms may include Gaussian pulses, Gaussian doublets, and higher-order Gaussian pulses. Conventional approaches to generating pulses for non-linear devices are often limited to specific wavelength bands relating to a particular frequency source.

While Gaussian pulses have many applications in short-range communications, Gaussian pulses contain rich direct-current (DC) spectral content and are not readily suitable for transmission through antennae. Pulse-shaping networks may be used to format Gaussian pulses in an acceptable format for antenna transmission. This is understood as a problem of transmitting radiated pulse characteristics via a practical antenna setup. To address this problem, a Gaussian pulse for transmission needs to be transformed or generated into higher derivatives by integrating it with pulse-shaping networks. Also, the UWB transmitters require features such as switching the pulse shapes between monocycle and Gaussian, tunable pulse duration, and pulse shape modulation (PSM).

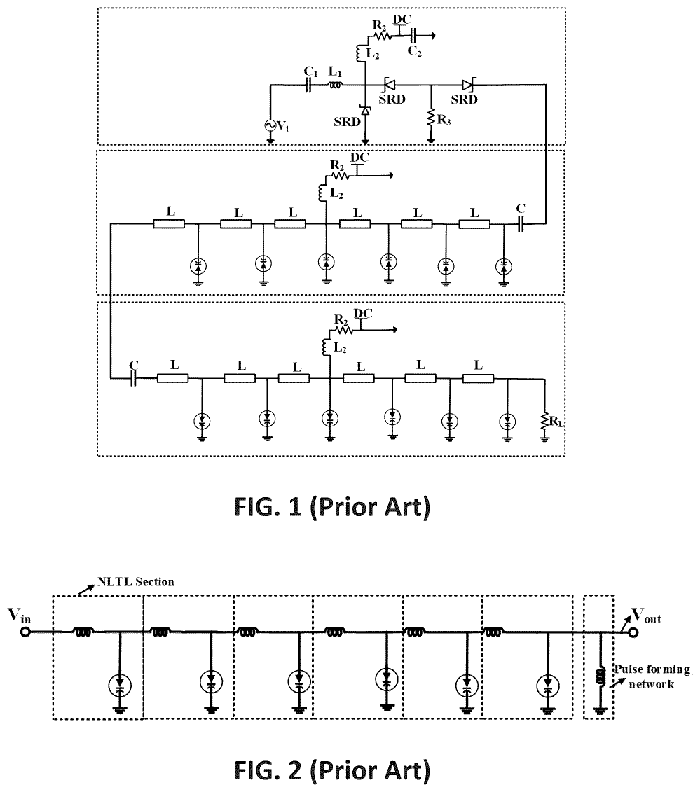

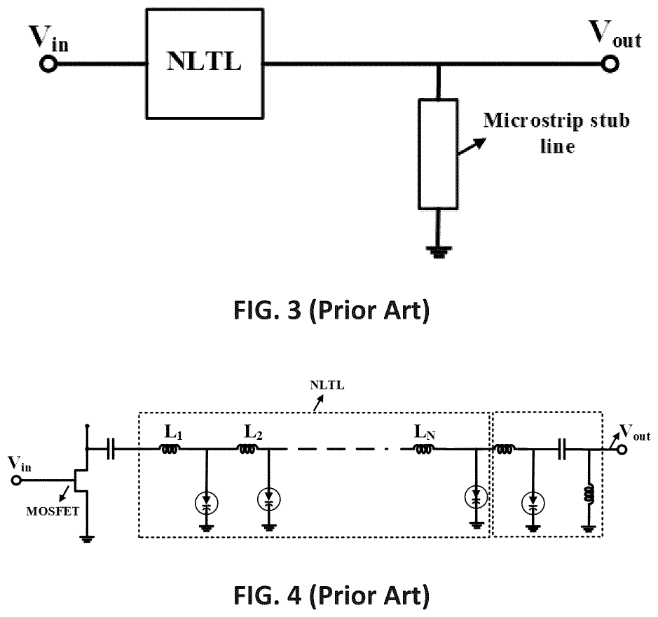

Existing pulse generators based on NLTLs focus on pulse compression capabilities by generating Gaussian pulses. FIG. 1 illustrates a prior-art pulse generator using NLTL-based compression techniques having a configuration where two different NLTL arms are utilized for corresponding rise- and fall-time compression along with the mixed combination of step recovery diodes to produce a clean ps pulse in the ps regime. As shown in FIG. 1, an existing circuit is provided having rise and fall time compression with an acceptable ringing level. Such NLTL-based pulse generators are suitable for a variety of applications including ultrafast systems, advanced biological treatments, imaging, and sensing applications. FIG. 2 illustrates a prior-art impulse-forming circuit for generating a negative-going Gaussian impulse generation based on NLTL in the nanosecond regime. FIG. 3 illustrates a prior-art NLTL waveform generator in accordance with microstrip waveguide line to develop a ps pulse at the output, wherein a microstrip stub line is loaded to the output side of the NLTL. FIG. 4 illustrates a prior-art pulse generator for producing a 200 ps high-voltage ultrashort pulse using NLTL with fixed inductors and variable capacitors that are coupled to the ground along with the metal-oxide-semiconductor field-effect transistor (MOSFET) driver input pulse, wherein a MOSFET driver is loaded to the input and a pulse-forming network integrated at the output side of NLTL. As shown in these figures, circuits are provided for pulse compression, which provide relatively short duration pulses, suitable for providing increased bandwidth for many applications, including for UWB radar applications.

While the pulse generator illustrated in FIG. 1 provides suitable rise-time and fall-time compression for Gaussian pulses, the same pulse generator is not suitable for corresponding higher Gaussian derivatives making it unsuitable for transmission via a practical antenna setup in such applications. Similarly, the pulse generators in FIG. 3 and FIG. 4 have pulse compression capabilities that are directed to fall-time reduction. There is an increased demand for transforming Gaussian pulses into higher derivatives comprising integration with pulse-shaping networks and having reduced pulse duration and mitigated ringing behavior. Further, the above referenced pulse compressors are primarily directed to generating a single Gaussian pulse, which has limited application in PSM as well as data encoding communication where different pulse levels are desirable. Further, the pulse compressors illustrated in FIG. 1 to FIG. 4 may generally exhibit ringing behavior that needs to be further reduced for particular applications.

In some embodiments disclosed herein, pulse generators are provided that comprise transformation of Gaussian pulses into higher derivatives and are suitable for developing corresponding doublets, therefore creating new pulse shapes. Specifically, Gaussian pulses may be transformed to corresponding Gaussian doublets and corresponding monocycle doublets. These pulses are suitable for UWB transmission using some embodiments disclosed herein.

In some embodiments disclosed herein, an NLTL may serve as a pulse compressor and as a delay line, providing two important functions. Ringing behavior may be addressed by some embodiments disclosed herein making the pulse compressor in these embodiments suitable for pulse compression and pulse shaping. These pulses may be transmitted via a practical antenna setup by integrating with a pulse-shaping network. These characteristics of the pulse compressors disclosed herein make them suitable for UWB application with PSM. Further, the pulse features described herein are desirable for many applications especially its utilization in the arbitrary waveform generator (AWG) devices and oscilloscopes.

Embodiments of pulse compressors disclosed herein provide low cost and simple Gaussian doublet generation based on NLTLs, transformation of simple Gaussian doublets to corresponding monocycle doublets, adjustable pulse to pulse duration without inherent restriction thereof, adjustable pulse compression capabilities, flexibility to transform pulses to other important pulse shapes by integrating a phase-shift network, extraordinary improvement in ringing behavior due to NLTLs, easy transformation of a pulse generator to the same-phase Gaussian doublet generator, easy customizable to more complex waveforms such as triplet Gaussian pulses, and provide a simple solution for avoiding dispersion effects.

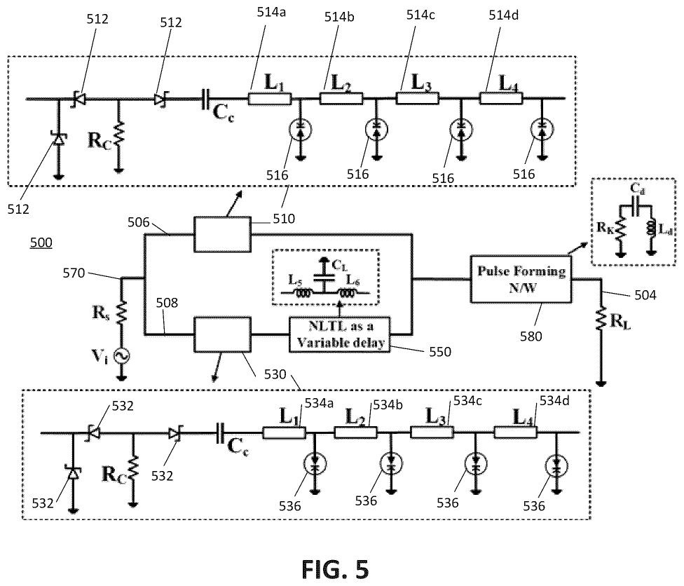

Referring to FIG. 5, in some embodiments, a pulse generator module 500 comprises an input port 502, an output port 504, and two conductive paths arranged in parallel connecting the input port 502 and the output port 504. The two conductive paths comprise a first conductive path 506 and a second conductive path 508. The first conductive path 506 comprises a first pulse compressor and the second conductive path 508 comprises a second pulse compressor and a delay element 550. In some embodiments, the pulse compressors are NLTL networks and may comprise active elements such as inductors, capacitors, diodes, varactors, and/or the like.

The first pulse compressor is a first NLTL 510. The first NLTL 510 comprises one or more step recovery diodes (SRDs) 512, a plurality of lumped inductors (514a and 514b and 514c and 514d), and a plurality of reversely biased varactor diodes 516. In these embodiments, the first NLTL 510 comprises four sections, wherein each section comprises an inductor and reversely biased varactor diodes. In some alternative embodiments, the first NLTL 510 may comprise five or more sections.

The second pulse compressor is a second NLTL 530. The second NLTL 530 comprises one or more SRDs 532, a plurality of lumped inductors (534a and 534b and 534c and 534d), and a plurality of reversely biased varactor diodes 536. In these embodiments, the second NLTL 530 comprises four sections, wherein each section comprises an inductor and reversely biased varactor diodes. In some alternative embodiments, the first NLTL 530 may comprise five or more sections. In these embodiments, the delay element 550 of the second conductive path 508 is an NLTL and may comprise an inductor (L₅), a capacitor (C_{L}), and an inductor (L₆).

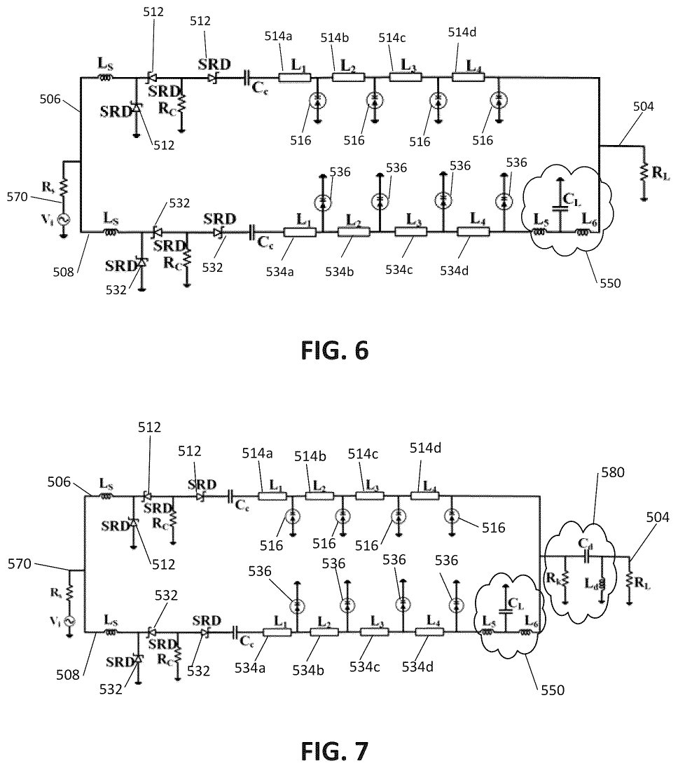

FIG. 6 shows an exemplary circuit of the module 500 acting as a Gaussian doublet pulse generator for providing a Gaussian doublet pulse, in accordance with the architecture shown in FIG. 5. FIG. 7 shows an exemplary circuit of the module 500 acting as a monocycle doublet pulse generator for providing a monocycle doublet pulse, in accordance with the architecture shown in FIG. 5 and further comprising a pulse-forming network 580. Referring to FIGS. 5 and 7, the pulse-forming network 580 is connected to the output port 504 and comprises a resistor (R_{K}), a capacitor (C_{d}) and an inductor (L_{d}).

Referring again to FIG. 5, a signal generator 570 provides an input pulse waveform (Vᵢ) where a source resistance of the signal generator 570 is represented by Rₛ.

In some embodiments disclosed herein, the module 500 comprises a mixed SRD topology for each of the first NLTL 510 and the second NLTL 530. The model for each SRD is as follows:

$$Q ( V ) = \{ \begin{matrix}{C}_{r} * {V}_{d} \to ( V \leq 0 ) \\ \frac{{C}_{f} - {C}_{r}}{2 {V}_{j}} ( V + \frac{{C}_{r} {V}_{j}}{{C}_{f} - {C}_{r}} ) - \frac{{C}_{r}^{2}}{2 ( {C}_{f} - {C}_{r} )} \times {V}_{j} \to ( 0 < V < {V}_{j} ) \\ {C}_{f} V - \frac{{C}_{f} - {C}_{r}}{2} {V}_{j} \to ( V \geq {V}_{j} )\end{matrix} \} \qquad ( 1 )$$

where Q stands for charge stored in the diode 512 or 532 of the first or second NLTL 510 or 530, V is the terminal voltage of the diode 512 or 532, Vⱼ is the built-in potential of the diode 512 or 532 under consideration, and C_{f} is the maximum value of the capacitance in a forward bias. Support for (1) can be found at least in “A Nonlinear Transmission Approach to Compressing Rise and Fall Time in Picosecond Pulse Generation” by MuhibUr et al. found in IEEE Transactions on Instrumentation and Measurement (Vol. 70, 2021), the entirety of which is hereby incorporated by reference. As an example, a MACOM™ MAVR-0447 series SRD having a transition time of 150 ps may be used for each of the first and second NLTL 510 and 530.

The first NLTL 510 is a pulse generator based on rise-time compression comprising a mixed SRD topology and an NLTL. The second NLTL 530 is a pulse generator based on fall-time compression comprising a mixed SRD topology and an NLTL comprising varactor diodes having an opposite polarity of the varactor diodes of the first NLTL 510.

In these embodiments, each of the first NLTL 510 and the second NLTL 530 comprise four sections, wherein each section comprises an inductor and a reversely biased varactor diode. In some embodiments, the first NLTL 510 comprises five or more sections. In some embodiments, each of the first NLTL 510 and the second NLTL 530 may comprises any number of sections but each additional section of an NLTL increases the size of the NLTL.

In these embodiments, the delay element 550 of the pulse generator is an NLTL, and may comprise an inductor (L₅), a capacitor (C_{L}), and an inductor (L₆). The delay element 550 may also be used to shape the pulse.

In these embodiments, the pulse-forming network 580 comprises a resistor (Rₖ), a capacitor (C_{d}), and an inductor (L_{d}), and is used for converting a Gaussian doublet pulse into a monocycle doublet pulse. In embodiments where the pulse generator is used for producing Gaussian doublet pulses, a pulse-forming network 580 may not be required.

Referring to FIG. 5 to FIG. 7, Rₛ represents the source resistance and RL represents the load resistance. The following table provides an example of values of parameters with corresponding tolerance of ±0.5% from a manufacturer.

| Parameter | Value | |
|---|---|---|
| Rₛ | 50 ohm | (Ω) |
| R_{L} | 50Ω | |
| R_{c} | 4.6 kiloohm | (kΩ) |
| R_{K} | 4 | kΩ |
| L₁ | 20 nanohenry | (nH) |
| L₂ | 20 | nH |
| L₃ | 20 | nH |
| L₄ | 20 | nH |
| L_{d} | 1.2 | nH |
| L_{S} | 20 | nH |
| L₅ = L₆ | 27 | nH |
| C_{c} | 100 nanofarad | (nF) |
| C_{d} | 1.5 picofarad | (pF) |
| C_{L} | 15 | pF |

Some of the parameters have a narrower tolerance range than others while other parameters may have a wider tolerance range. For example, in the above table, Re may have any values in the range of about 4 kΩ to 5 kΩ, R_{K} may have any value in the range of about 3 kΩ to 6 k Ω, and La may have a value in the range of about 1 nH to 1.5 nH.

Some embodiments disclosed herein are suitable for use in a variety of applications. For example, they may be used in AWGs, which are important components in the field of electronics and photonics systems, and some embodiments of pulse generators provided herein may be suitable for future applications. As another example, embodiments of pulse generators disclosed herein may be suitable for ultrafast electronic circuits, interconnects, and systems as a result of ultrashort pulse duration with multiple pulse shaping. As a further example, embodiments of pulse generators disclosed herein may be used in UWB communication systems for a frequency spectrum corresponding to the UWB spectrum and for eliminating DC spectral contents by transforming the DC spectral contents into higher derivatives.

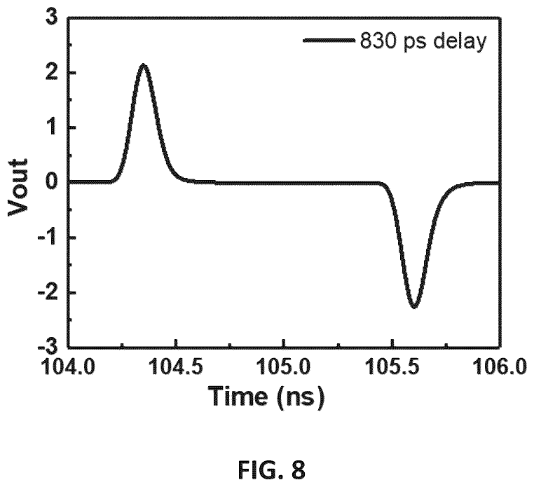

Pulse compression is achieved in above-described Gaussian doublet pulse generator (formed by the module 500 as shown in FIG. 6) along with properly maintaining a suitable ringing behavior. This compression can be seen parametrically from FIG. 8 to FIG. 10 by adjusting the NLTL delay network utilized. There is no ringing behavior generation even in case of compression and delay adjustment. The Gaussian doublet pulse generator may also be transformed to a same-phase Gaussian doublet generator by changing the polarities of the varactor diodes of the second NLTL 530 to possess opposite polarities of the varactor diodes of the first NLTL 510.

The Gaussian doublet pulse generator shown in FIG. 6 comprises rise- and fall-time NLTL-based pulse generators for receiving sinusoidal input signals mirroring each other with respect to selected amplitude levels, along with a variable delay element 550. An extra NLTL section is used as a time-delay element for one pulse generator, such that the output of one pulse generator is delayed with respect to the other. The time-delay element may be adjusted to tune the delay width as illustrated in FIG. 8 to FIG. 10 to reduce the delay from about 830 ps to 100 ps.

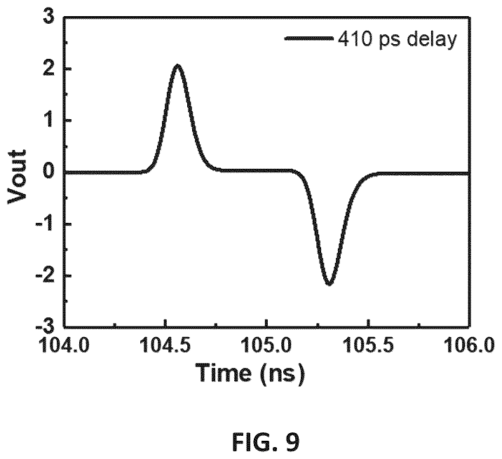

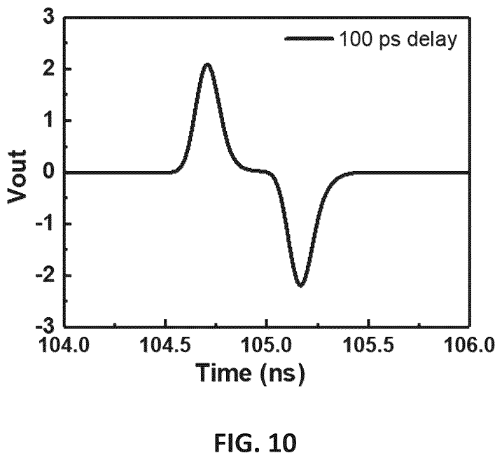

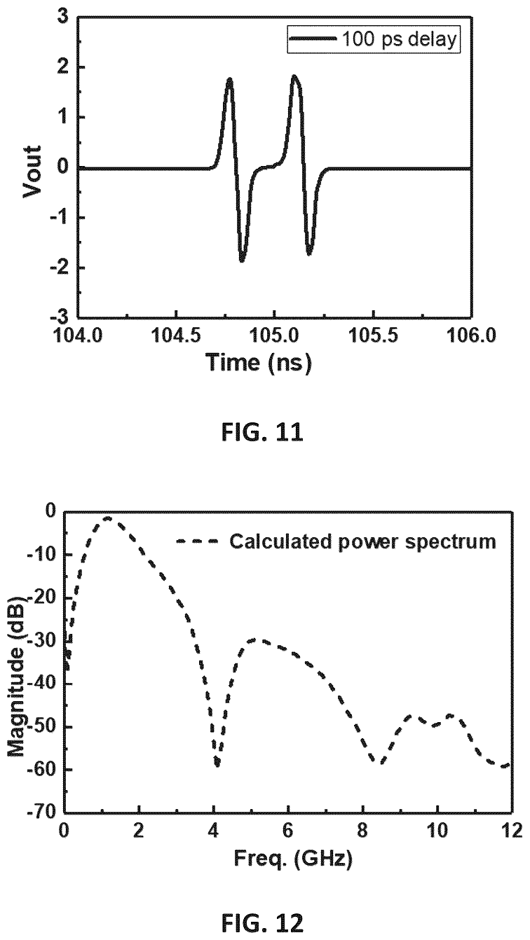

FIG. 8 illustrates a response of an embodiment of a Gaussian doublet pulse generator with the extra NLTL section wherein the delay between pulses is adjusted to 830 ps. FIG. 9 illustrates a response of an embodiment of a Gaussian doublet pulse generator with the extra NLTL section wherein the delay between pulses is adjusted to 410 ps. FIG. 10 illustrates a response of an embodiment of a Gaussian doublet pulse generator with the extra NLTL section wherein the delay between pulses is adjusted to 100 ps. FIG. 11 illustrates a response of an embodiment of a monocycle doublet pulse generator with the extra NLTL section wherein the delay between pulses is adjusted to 100 ps.

In some embodiments of the modules and methods disclosed herein, step delay may be controlled to provide a desired pulse width. The value of Re may be selected to control compression capability of a pulse as shown in FIG. 5 and the value of the resistor Rₖ may be selected to provide the corresponding matching and ringing reduction.

To use the pulse generator in practical transmission, the rich DC spectral contents present in Gaussian doublets may need to be eliminated. In some embodiments, a monocycle doublet pulse generator may be utilized instead of the Gaussian doublet. For example, for chip-to-chip interconnection, a Gaussian doublet may be preferable while for free-space communication including UWB radars a corresponding monocycle doublet may be preferable. An example of the calculated power spectrum of the monocycle doublet pulse generator as shown in FIG. 12 covers the UWB frequency range by eliminating rich DC spectral contents.

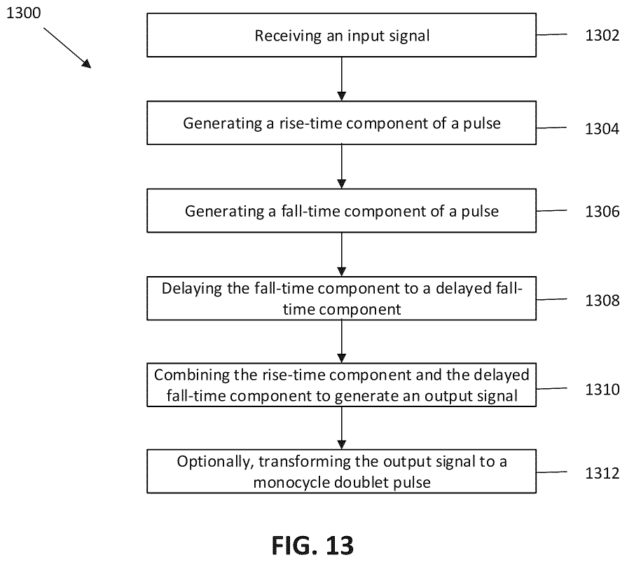

FIG. 13 is a flowchart showing the steps of a method 1300, according to some embodiments of the present disclosure. The method 1300 begins with receiving an input signal (step 1302). At step 1304, a rise-time component of a pulse is generated. At step 1306, a fall-time component of a pulse is generated. At step 1308, the fall-time component is delayed to provide a delayed fall-time component. At step 1310, the rise-time component and the delayed fall-time component are combined to generate an output signal. Optionally, at step 1312, the output signal is transformed to a monocycle doublet pulse.

1. A circuit comprising:
an input port;
an output port; and
a first conductive path and a second conductive path arranged in parallel and connecting the input port and the output port,
the first conductive path comprising a first pulse compressor, and
the second conductive path comprising a second pulse compressor and a delay element.

2. The circuit of claim 1, wherein the first pulse compressor comprises a first non-linear transmission line (NLTL) comprising one or more step recovery diodes (SRDs).

3. The circuit of claim 2, wherein the first pulse compressor comprises lumped inductors and reversely biased varactor diodes.

4. The circuit of claim 2, wherein the first NLTL comprises four sections.

5. The circuit of claim 2, wherein the first NLTL comprises five or more sections.

6. The circuit of claim 1, wherein the second pulse compressor comprises a second NLTL comprising one or more SRDs.

7. The circuit of claim 6, wherein the second pulse compressor comprises lumped inductors and reversely biased varactor diodes.

8. The circuit of claim 6, wherein the second NLTL comprises four sections.

9. The circuit of claim 6, wherein the second NLTL comprises five or more sections.

10. The circuit of claim 1, wherein the first pulse compressor comprises a first NLTL comprising first one or more varactor diodes for rise-time compression, and the second pulse compressor comprises a second NLTL comprising second one or more varactor diodes for fall-time compression, the second one or more varactor diodes of the second NLTL arranged with a second polarity opposite a first polarity of the first one or more varactor diodes of the first NLTL.

11. The circuit of claim 1, wherein the delay element comprises a variable delay network.

12. The circuit of claim 1, wherein the delay element comprises an NLTL.

13. The circuit of claim 12, wherein the delay element comprises lumped inductors and reversely biased varactor diodes.

14. The circuit of claim 1, wherein the circuit is for generation of a Gaussian doublet pulse.

15. The circuit of claim 1, further comprising a pulse-forming network proximate the output port.

16. The circuit of claim 15, wherein the pulse-forming network is for transforming a Gaussian doublet pulse to a monocycle doublet pulse.

17. A method comprising the steps of:
receiving an input signal;
generating a rise-time component of a pulse;
generating a fall-time component of the pulse;
delaying the fall-time component to a delayed fall-time component; and
combining the rise-time component and the delayed fall-time component to generate an output signal.

18. The method of claim 17, wherein the fall-time component is delayed by an adjustable delay.

19. The method of claim 17, wherein the output signal comprises a Gaussian doublet pulse.

20. The method of claim 19, further comprising:
transforming the Gaussian doublet pulse to a monocycle doublet pulse.
